(19) United States
(12) Patent Application Publication
(10) Pub. No.: US 2024/0380830 A1
(43) Pub. Date: Nov. 14, 2024

(54) DISPLAY DEVICE

(71) Applicant: Samsung Display Co., Ltd., Yongin-si (KR)

(72) Inventor: SUCHANG RYU, Yongin-si (KR)

(21) Appl. No.: 18/598,749

(22) Filed: Mar. 7, 2024

(30) Foreign Application Priority Data
May 8, 2023 (KR) 10-2023-0058983

(51) Int. Cl. H04M 1/02

(52) U.S. Cl. CPC H04M 1/0222

(57) ABSTRACT

A display device includes a display panel including a folding region folded based on a folding axis extended in a first direction, and a first non-folding region and a second non-folding region spaced from one another and having the folding region interposed therebetween; a support layer below the display panel; and a support adhesive layer below the support layer, wherein the support layer includes: a first glass substrate including a first portion having a first thickness and a second portion having a second thickness less than the first thickness, and overlapping the first non-folding region; a second glass substrate including a third portion having a third thickness and a fourth portion having a fourth thickness less than the third thickness, spaced from the first glass substrate, and overlapping the second non-folding region; and a resin layer between the first glass substrate and the second glass substrate.

### CROSS-REFERENCE TO RELATED APPLICATION

The present application claims priority to and the benefit of Korean Patent Application No. 10-2023-0058983, filed on May 8, 2023, in the Korean Intellectual Property Office, the entire disclosure of which is incorporated herein by reference.

### BACKGROUND

### 1. Field

Aspects of embodiments of the present disclosure relate to a display device.

### 2. Description of the Related Art

A display device includes an active region activated in accordance with an electrical signal. The display device may sense an input applied from the outside through the active region, and simultaneously display various images to provide information to a user. With the recent development of display devices having various shapes, active regions having various shapes are implemented.

Flexible display devices including a flexible display panel which is foldable are being developed. A flexible display device may be folded, rolled, or bent unlike a rigid electronic device. A flexible display device, the shape of which may be variously changed, may be portable regardless of the original screen size thereof, so that user convenience may be improved. Members constituting the flexible display device may be provided separated into two or more components which do not overlap a flexible region according to the flexible properties, and there is a problem in that the components are separated when an external impact occurs.

The above information disclosed in this Background section is only for enhancement of understanding of the background of the invention and therefore it may contain information that does not form the prior art.

### SUMMARY

Aspects of embodiments of the present disclosure are directed to a display device including a first glass substrate and a second glass substrate directly disposed under a display panel and spaced apart from each other.

According to some embodiments of the present disclosure are directed to a display device including: a display panel including a folding region folded based on a folding axis extended in a first direction, and a first non-folding region and a second non-folding region spaced from one another and having the folding region interposed therebetween; a support layer below the display panel; and a support adhesive layer below the support layer, wherein the support layer includes: a first glass substrate including a first portion having a first thickness and a second portion having a second thickness less than the first thickness, and overlapping the first non-folding region; a second glass substrate including a third portion having a third thickness and a fourth portion having a fourth thickness less than the third thickness, spaced from the first glass substrate, and overlapping the second non-folding region; and a resin layer between the first glass substrate and the second glass substrate.

In some embodiments, the support layer is directly below the display panel.

In some embodiments, the first glass substrate and the second glass substrate do not overlap the folding region.

In some embodiments, the first glass substrate further includes a fifth portion between the first portion and the second portion and having a first inclined surface; and the second glass substrate further includes a sixth portion between the third portion and the fourth portion and having a second inclined surface.

In some embodiments, the resin layer includes a first resin portion overlapping the folding region, a second resin portion overlapping the first non-folding region, and a third resin portion overlapping the second non-folding region.

In some embodiments, the first resin portion includes: a first sub-resin portion adjacent to the display panel; and a second sub-resin portion having a Young's modulus different from that of the first sub-resin portion, and positioned below the first sub-resin portion.

In some embodiments, the Young's modulus of the first sub-resin portion is different from a Young's modulus of the second resin portion and a Young's modulus of the third resin portion.

In some embodiments, the first sub-resin portion is between the second portion and the fourth portion, and the second sub-resin portion is between the first portion and the third portion.

In some embodiments, the second resin portion overlaps the second portion, and does not overlap the first portion; and the third resin portion overlaps the fourth portion, and does not overlap the third portion.

In some embodiments, a thickness of the first resin portion is greater than a thickness of the second resin portion and a thickness of the third resin portion.

In some embodiments, the resin layer includes a thermosetting resin or a photo-curable resin.

In some embodiments, at a temperature of 25° C., the Young's modulus of the resin layer is 100 MPa or less.

In some embodiments, the support adhesive layer does not include a pressure sensitive adhesive (PSA).

In some embodiments, the support adhesive layer includes a first adhesive layer and a second adhesive layer spaced from each other in a second direction crossing the first direction.

In some embodiments, the support adhesive layer includes: a first region overlapping the first glass substrate or the second glass substrate, and not overlapping the resin layer; and a second region overlapping the resin layer.

In some embodiments, a portion of the second region overlaps the folding region.

In some embodiments, the support adhesive layer includes a base portion and an adhesive portion above the base portion.

In some embodiments, the support adhesive layer further includes a sub-adhesive portion below the base portion.

In some embodiments, the display device further includes a metal layer below the support adhesive layer and not overlapping the folding region.

In some embodiments, the display device further includes a polymer film overlapping the folding region, the first non-folding region, and the second non-folding region, and directly below the support adhesive layer.

### BRIEF DESCRIPTION OF THE DRAWINGS

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1A is a perspective view of a display device in an unfolded state according to some embodiments of the inventive concept;

FIG. 1B is a perspective view showing a folding operation of a display device according to some embodiments of the inventive concept;

FIG. 1C is a plan view of a display device in a folded state according to some embodiments of the inventive concept;

FIG. 1D is a perspective view showing a folding operation of a display device according to some embodiments of the inventive concept;

FIG. 2 is an exploded perspective view of a display device according to some embodiments of the inventive concept;

FIG. 3 is a cross-sectional view showing a portion corresponding to the line I-I′ of FIG. 2, according to some embodiments of the inventive concept;

FIG. 4 is a cross-sectional view showing a portion of a display device according to some embodiments of the inventive concept;

FIG. 5 is a cross-sectional view showing a portion of a display device according to some embodiments of the inventive concept;

FIG. 6 is a plan view showing a portion of a display device according to some embodiments of the inventive concept;

FIG. 7A is a cross-sectional view showing a portion of a display device according to some embodiments of the inventive concept;

FIG. 7B is a cross-sectional view showing a portion of a display device according to some embodiments of the inventive concept;

FIG. 8 is a cross-sectional view showing a display device of the related art;

FIG. 9 is a cross-sectional view showing a portion of a display device according to some embodiments of the inventive concept;

FIG. 10 is a cross-sectional view showing a portion of a display device according to some embodiments of the inventive concept;

FIG. 11 is a cross-sectional view showing a portion of a display device according to some embodiments of the inventive concept;

FIG. 12 is a cross-sectional view showing a portion of a display device according to some embodiments of the inventive concept;

FIG. 13 is a cross-sectional view showing a portion of a display device according to an embodiment of the inventive concept;

FIG. 14 is a cross-sectional view showing a portion of a display device according to some embodiments of the inventive concept;

FIG. 15 is a cross-sectional view showing a portion corresponding to the line X-X′ of FIG. 1C, according to some embodiments of the inventive concept;

FIG. 16A is a graph showing strains as measured according to the Young's modulus and thickness of a resin layer;

FIG. 16B is a graph showing strains as measured according to the Young's modulus and thickness of a resin layer;

FIG. 16C is a graph showing strains as measured according to the Young's modulus and thickness of a resin layer; and

FIG. 16D is a graph showing strains as measured according to the Young's modulus and thickness of a resin layer.

### DETAILED DESCRIPTION

The inventive concept may be modified in many alternate forms, and thus specific embodiments will be exemplified in the drawings and described in detail. It should be understood, however, that it is not intended to limit the inventive concept to the particular forms disclosed, but rather, is intended to cover all modifications, equivalents, and alternatives falling within the spirit and scope of the inventive concept.

Unless otherwise defined, all terms (including technical and scientific terms) used herein have the same meaning as commonly understood by one of ordinary skill in the art to which the present invention pertains. It is also to be understood that terms such as terms defined in commonly used dictionaries should be interpreted as having meanings consistent with the meanings in the context of the related art, and should not be interpreted in too ideal a sense or an overly formal sense unless explicitly defined herein.

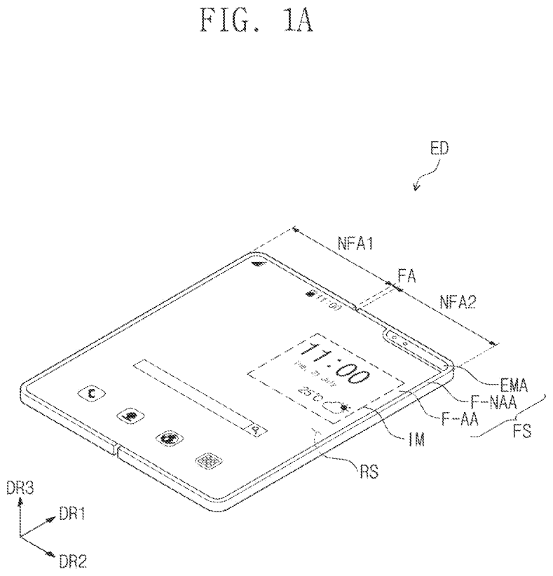

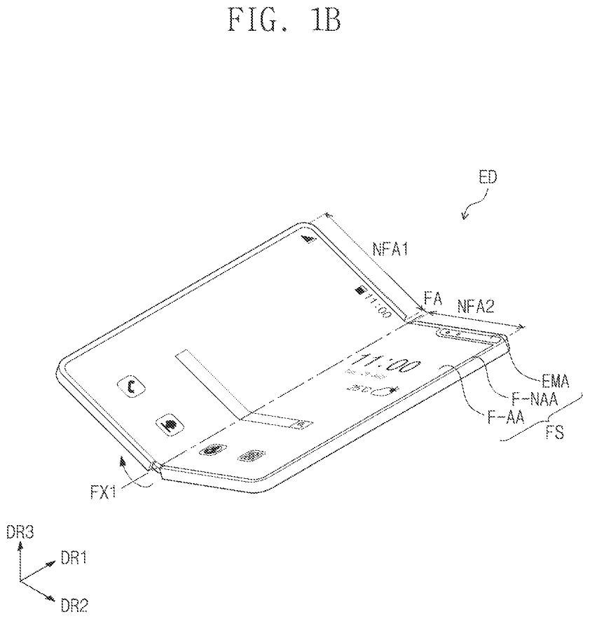

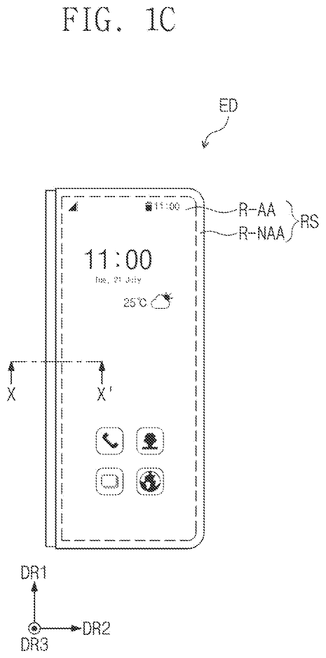

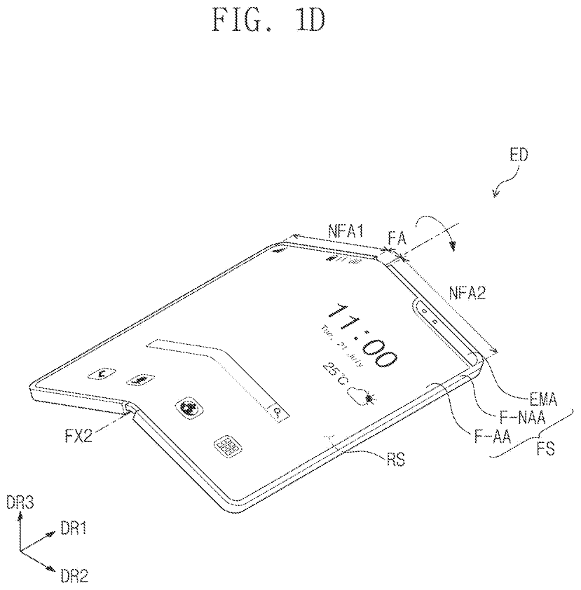

Hereinafter, a display device according to some embodiments of the inventive concept will be described with reference to the accompanying drawings. FIG. 1A is a perspective view of a display device ED in an unfolded state according to some embodiments of the inventive concept.

The display device ED of some embodiments is a device activated by an electrical signal. For example, the display device ED may be a mobile phone, a tablet computer, a car navigation system, a game console, or a wearable device; however, embodiments of the inventive concept are not limited thereto. In FIG. 1A and the like, the display device ED is exemplarily illustrated as a mobile phone.

The display device ED may include a first display surface FS defined by a first direction axis DR1 and a second direction axis DR2 crossing the first direction axis DR1. The display device ED may provide an image IM to a user through the first display surface FS. The display device ED may display the image IM toward a third direction axis DR3 direction on the first display surface FS parallel to each of the first direction axis DR1 and a second direction axis DR2.

As used herein, the first direction axis DR1 and the second direction axis DR2 are perpendicular to each other, and the third direction axis DR3 may be a normal direction with respect to a plane defined by the first direction axis DR1 and the second direction axis DR2. A thickness direction of the display device ED may be a direction parallel to the third direction axis DR3. A front surface (or upper surface) and a rear surface (or lower surface) oppose each other in the third direction axis DR3, and the normal direction of each of the front surface (or upper surface) and the rear surface (or lower surface) may be parallel to the third direction axis DR3. The front surface (or upper surface) refers to a surface adjacent to the first display surface FS, and the rear surface (or lower surface) refers to a surface spaced apart from the first display surface FS. In addition, the rear surface (or lower surface) refers to a surface close to a second display surface RS.

A cross-section refers to a surface parallel to the thickness direction DR3, and a plane refers to a surface perpendicular to the thickness direction DR3. The plane refers to a plane defined by the first direction axis DR1 and the second direction axis DR2.

Directions indicated by the first to third direction axes DR1, DR2, and DR3 described herein are a relative concept, and may be converted into different directions. In addition, the directions indicated by the first to third direction axes DR1, DR2, and DR3 may be described as first to third directions, and may be denoted by the same reference numerals.

The display device ED may sense an external input applied from the outside. The external input may include various suitable forms of inputs provided from the outside of the display device ED. For example, the external input may include not only a contact by a part of a user's body, such as a hand, but also an external input applied in close proximity to the display device ED, or adjacent thereto at a set or predetermined distance (for example, hovering above the display device ED). Also, the external input may have various suitable forms, such as force, pressure, temperature, light, and the like.

The display device ED may include the first display surface FS and the second display surface RS. The first display surface FS may include a first active region F-AA, a first peripheral region F-NAA, and an electronic module region EMA. The second display surface RS may be defined as a surface opposing at least a portion of the first display surface FS. That is, the second display surface RS may be defined as a portion of the rear surface of the display device ED.

The first active region F-AA may be a region activated by electrical signals. The first active region F-AA may be a region in which the image IM is displayed, and which may sense an external input of various suitable forms.

The first peripheral region F-NAA may be adjacent to the first active region F-AA. The first peripheral region F-NAA may have a set or predetermined color. The first peripheral region F-NAA may surround the first active region F-AA. Accordingly, the shape of the first active region F-AA may be substantially defined by the first peripheral region F-NAA. However, this is only exemplary, and the first peripheral region F-NAA may be disposed adjacent to only one side of the first active region F-AA, or may be omitted.

In the electronic module region EMA, various suitable electronic modules may be disposed. For example, an electronic module may include at least one of a camera, a speaker, a light sensing sensor, or a heat sensing sensor. The electronic module region EMA may sense an external object received through the display surfaces FS and RS, or may provide a sound signal such as voice to the outside through the display surfaces FS and RS. The electronic module may include a plurality of components, and is not limited to any one embodiment.

The electronic module region EMA may be surrounded by the first peripheral region F-NAA. However, this is only exemplary, and embodiments of the inventive concept are not limited to thereto. For example, the electronic module region EMA may be surrounded by the first active region F-AA and the first peripheral region F-NAA, or the electronic module region EMA may be disposed inside the first active region F-AA.

The display device ED according to some embodiments includes at least one folding region FA and a plurality of non-folding regions NFA1 and NFA2 extended from the folding region FA. For example, a first non-folding region NFA1, the folding region FA, and a second non-folding region NFA2 may be defined along the second direction DR2. The display device ED of some embodiments includes the first non-folding region NFA1 and the second non-folding region NFA2 spaced apart from each other in the second direction DR2 with the folding region FA interposed therebetween. For example, the first non-folding region NFA1 may be disposed on one side of the folding region FA along the second direction DR2, and the second non-folding region NFA2 may be disposed on the other side of the folding region FA along the second direction DR2.

In FIG. 1A and the like, some embodiments of the display device ED including one folding region FA is illustrated; however, embodiments of the inventive concept are not limited thereto, and the display device ED may have a plurality of folding regions defined therein. For example, a display device according to some embodiments includes two or more folding regions, and may include three or more non-folding regions disposed with each of the folding regions interposed therebetween.

FIG. 1B is a perspective view showing a folding operation of the display device ED according to some embodiments of the inventive concept. FIG. 1C is a plan view of the display device ED in a folded state according to some embodiments of the inventive concept. FIG. 1D is a perspective view showing a folding operation of the display device ED according to some embodiments of the inventive concept.

Referring to FIG. 1B, the display device ED according to some embodiments is folded based on a first folding axis FX1 extended in the first direction DR1. When the display device ED is in a folded state, the folding region FA may have a set or predetermined curvature and a radius of curvature. The display device ED may be folded based on the first folding axis FX1 so as to be transformed into an in-folding state in which the first non-folding region NFA1 and the second non-folding region NFA2 face each other, and the first display surface FS is not exposed to the outside.

Referring to FIG. 1C, when the display device ED according to some embodiments is in the in-folding state, the second display surface RS may be visually recognized by a user. In this state, the second display surface RS may include a second active region R-AA which displays an image. The second active region R-AA may be a region activated by an electrical signal. The second active region R-AA may be a region in which an image is displayed, and which may sense an external input of various suitable forms.

A second peripheral region R-NAA may be adjacent to the second active region R-AA. The second peripheral region R-NAA may have a set or predetermined color. The second peripheral region R-NAA may surround the second active region R-AA. In addition, the display device ED may further include an electronic module region in which an electronic module including various suitable components is disposed on the second display surface RS, but is not limited to any one embodiment.

Referring to FIG. 1D, the display device ED according to some embodiments is folded based on a second folding axis FX2 extended in the first direction DR1. The display device ED may be folded based on the second folding axis FX2 so as to be transformed into an out-folding state such that the first display surface FS is exposed to the outside. In some embodiments, the display device ED is configured such that an in-folding or out-folding operation may be alternately repeated from an un-folding operation, but the embodiment of the inventive concept is not limitation thereto.

In FIG. 1A to FIG. 1D, it is exemplarily illustrated that the display device ED is folded based on one folding axis FX1 or FX2, but the number of folding axes and the number of non-folding regions in accordance therewith are not limited thereto. For example, the display device ED may be folded based on a plurality of folding axes so as to be folded such that a portion of each of the first display surface FS and the second display surface RS face each other. In addition, the first and second folding axes FX1 and FX2 are illustrated to be parallel to a long side of the display device ED; however, embodiments are not limited thereto, and the first and second folding axes FX1 and FX2 may be parallel to a short side of the display device ED.

In the display device ED, as illustrated in FIG. 1C, the first non-folding region NFA1 and the second non-folding region NFA2 may be defined as a portion having the display surfaces FS and RS which are parallel to the plane defined by the first direction axis DR1 and the second direction axis DR2 in a folded state, and the folding region FA may be defined as a region between the first non-folding region NFA1 and the second non-folding region NFA2. The folding region FA may include a curved surface portion which is bent to have a set or predetermined curvature in a folded state.

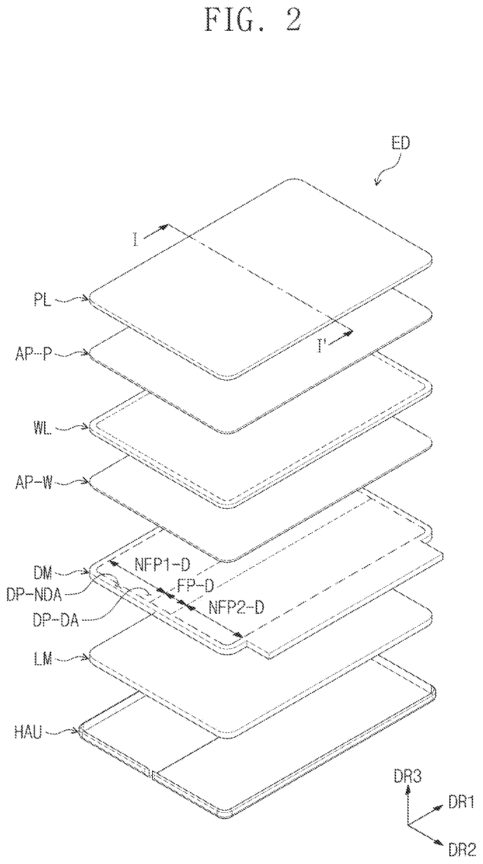

FIG. 2 is an exploded perspective view of the display device ED according to some embodiments of the inventive concept. Referring to FIG. 2, the display device ED may include a lower module LM, a display module DM disposed on an upper side of (e.g., above) the lower module LM, a window WP disposed on an upper side of (e.g., above) the display module DM, and a protection layer PL disposed on an upper side of (e.g., above) the window WL. In addition, the display device ED may further include a housing HAU.

The housing HAU may include a material having relatively high rigidity. For example, the housing HAU may include a plurality of frames and/or plates composed of glass, plastic, a metal, and/or the like. The housing HAU may provide a set or predetermined accommodation space. The display module DM may be accommodated in the accommodation space to be protected from an external impact.

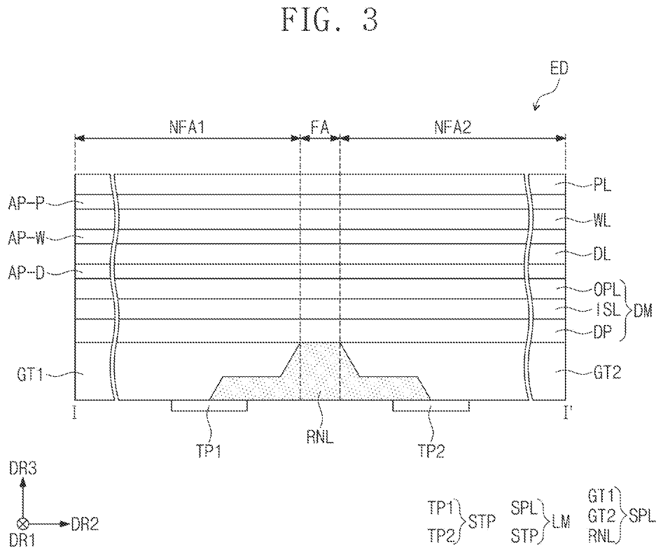

The lower module LM may be disposed on a lower side of (e.g., below) the display module DM. The lower module LM may include a support layer SPL (see, e.g., FIG. 3) and a support adhesive layer STP (see, e.g., FIG. 3), which are to be described later. The lower module LM may further include a digitizer, a cushion layer, a shielding layer, and the like. The cushion layer may include an elastomer such as sponge, foam, a urethane resin, or the like. The shielding layer may be an electromagnetic wave shielding layer or a heat dissipation layer. The lower module LM will be described in more detail later.

The display module DM displays an image in accordance with an electrical signal, and may transmit/receive information on an external input. The display module DM may include a display region DP-DA and a non-display region DP-NDA. The display region DP-DA may be defined as a region which emits an image provided from the display module DM.

The non-display region DP-NDA may be adjacent to the display region DP-DA. For example, the non-display region DP-NDA may surround the display region DP-DA. However, this is only exemplary, and the non-display region DP-NDA may be defined in various suitable shapes, and is not limited to any one embodiment. According to some embodiments, the display region DP-DA of the display module DM corresponds to at least a portion of the first active region F-AA (see, e.g., FIG. 1A).

The display module DM may include a folding display portion FP-D and non-folding display portions NFP1-D and NFP2-D. The folding display portion FP-D may be a portion corresponding to the folding region FA (see, e.g., FIG. 1A), and the non-folding display portions NFP1-D and NFP2-D may be portions corresponding to the non-folding regions NFA1 and NFA2 (see, e.g., FIG. 1A).

The folding display portion FP-D may correspond to a portion folded or bent based on the folding axes FX1 and FX2 (see, e.g., FIGS. 1B and 1D). The non-folding display portions NFP1-D and NFP2-D may include a first non-folding display portion NFP1-D and a second non-folding display portion NFP2-D. The first non-folding display portion NFP1-D and the second non-folding display portion NFP2-D may be spaced apart from each other in the second direction DR2 with the folding display portion FP-D interposed therebetween. The first non-folding display portion NFP1-D may be a portion corresponding to the first non-folding region NFA1. The second non-folding display portion NFP2-D may be a portion corresponding to the second non-folding region NFA2.

The window WL may include a polymer substrate or a glass substrate. For example, the window WL may include a glass substrate. The image IM (see, e.g., FIG. 1A) generated in the display module DM may transmit the window WL to be provided to a user. For example, the window WL may include an ultra-thin glass (UTG).

The protection layer PL may be a functional layer protecting one surface of the window WL. The protection layer PL may include an anti-fingerprint coating agent, a hard coating agent, an anti-static agent, and/or the like.

The display device ED may further include a window adhesive layer AP-W and a protection layer adhesive layer AP-P. The window adhesive layer AP-W may be disposed between the display module DM and the window WL. The display module DM and the window WL may be coupled to each other by the window adhesive layer AP-W. The protection layer adhesive layer AP-P may be disposed between the window WL and the protection layer PL. The window WL and the protection layer PL may be coupled to each other by the protection layer adhesive layer AP-P.

The window adhesive layer AP-W and the protection layer adhesive layer AP-P may include an adhesive or a pressure-sensitive adhesive. For example, the window adhesive layer AP-W and the protection layer adhesive layer AP-P may include a pressure sensitive adhesive (PSA) layer, an optically clear adhesive (OCA) film, an optically clear adhesive resin (OCR) layer, and/or the like. However, this is only exemplary, and the embodiment of the inventive concept is not limited thereto. Unlike what is illustrated, at least one of the window adhesive layer AP-W and the protection layer adhesive layer AP-P may be omitted.

FIG. 3 is a cross-sectional view showing a portion corresponding to the line I-I′ of FIG. 2, according to some embodiments of the inventive concept. FIG. 3 may be a cross-sectional view showing the display device ED according to some embodiments of the inventive concept. The contents described with reference to FIG. 2 may be equally applied to the window WL, the protection layer PL, the window adhesive layer AP-W, and the protection layer adhesive layer AP-P illustrated in FIG. 3.

Referring to FIG. 3, the display device ED may further include an upper film DL disposed between the display module DM and the window WL. The upper film DL may include a synthetic resin film. The upper film DL may absorb an external input applied to the front surface of the display device ED. However, embodiments of the present disclosure are not limited thereto, and the upper film DL may be omitted in some examples.

An upper adhesive layer AP-D may be disposed between the upper film DL and the display module DM. The upper film DL and the display module DM may be coupled to each other by the upper adhesive layer AP-D. The upper adhesive layer AP-D may include an adhesive or a pressure-sensitive adhesive. For example, the upper adhesive layer AP-D may include a pressure sensitive adhesive (PSA), an optically clear adhesive (OCA) film, an optically clear adhesive resin (OCR) layer, and/or the like. However, embodiments of the present disclosure are not limited thereto, and the upper adhesive layer AP-D may be omitted.

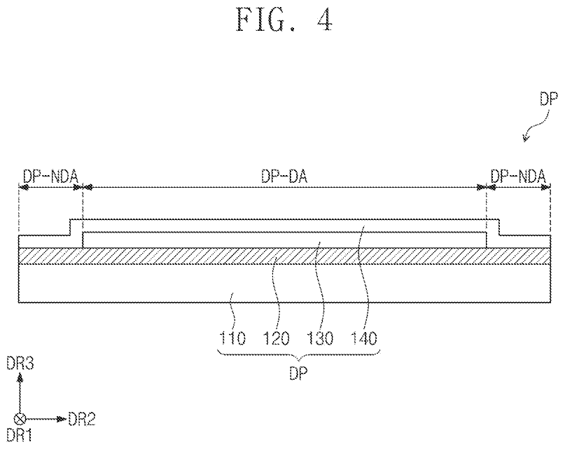

The display module DM may include a display panel DP, an input sensing layer ISL, and an optical layer OPL. The display panel DP may be a component which substantially generates an image. FIG. 4 is a cross-sectional view showing the display panel DP, according to some embodiments of the inventive concept.

Referring to FIG. 4, the display panel DP may include a base layer 110, a circuit layer 120 disposed on an upper side of (e.g., above) the base layer 110, a display element layer 130 disposed on an upper side of (e.g., above) the circuit layer 120, and an encapsulation layer 140 disposed on an upper side of (e.g., above) the display element layer 130.

The base layer 110 may provide a base surface on which the circuit layer 120 is disposed. The base layer 110 may be a flexible substrate capable of bending, folding, rolling, and the like. The base layer 110 may be a glass substrate, a metal substrate, a polymer substrate, or the like. However, embodiments of the inventive concept are not limited thereto, and the base layer 110 may include an inorganic layer, an organic layer, or a composite material layer.

The base layer 110 may include a single layer or multiple layers. For example, the base layer 110 may include a first synthetic resin layer, a multi-layered or single-layered inorganic layer, and a second synthetic resin layer disposed on an upper side of (e.g., above) the multi-layered or single-layered inorganic layer. Each of the first synthetic resin layer and the second synthetic resin layer may include a polyimide-based resin. In addition, each of the first synthetic resin layer and the second synthetic resin layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, a perylene-based resin, and/or the like. As used herein, a “˜˜-based” resin means that a functional group of the “˜˜” is included.

The circuit layer 120 may be disposed on an upper side of (e.g., above) the base layer 110. The circuit layer 120 may include an insulation layer, a semiconductor pattern, a conductive pattern, a signal line, and the like. The display element layer 130 may be disposed on an upper side of (e.g., above) the circuit layer 120. The display element layer 130 may be disposed in the display region DP-DA. The display element layer 130 may include a light emitting element. For example, the light emitting element may include an organic light emitting material, an inorganic light emitting material, an organic-inorganic light emitting material, a quantum dot, a quantum rod, a micro-LED, a nano-LED, and/or the like.

The encapsulation layer 140 may be disposed on an upper side of (e.g., above) the display element layer 130. The encapsulation layer 140 may protect the display element layer 130 from foreign materials such as moisture, oxygen, dust particles, debris, and/or the like. The encapsulation layer 140 may include at least one inorganic layer. For example, the encapsulation layer 140 may include a structure in which an inorganic layer, an organic layer, and an inorganic layer are sequentially stacked.

Referring back to FIG. 3, the input sensing layer ISL may be disposed on an upper side of (e.g., above) the display panel DP. The input sensing layer ISL may be directly disposed on an upper side of (e.g., above) the encapsulation layer 140 (see, e.g., FIG. 4). An adhesive member may be disposed between the input sensing layer ISL and the display panel DP.

As used herein, when one element is directly disposed on an upper side or lower side of (e.g., above or below) another element, it means that there is no third element disposed between the one element and the another element. That is, when one element is “directly disposed” on an upper side or lower side of (e.g., above or below) another element, it means that the one element and the another element are in “contact” with each other.

The input sensing layer ISL may sense an external input, change the external input to a set or predetermined input signal, and provide the input signal to the display panel DP. For example, the input sensing layer ISL may be a touch sensing layer which senses a touch. The input sensing layer ISL may recognize a user's direct touch, a user's indirect touch, a direct touch of an object, an indirect touch of an object, or the like.

The input sensing layer ISL may sense at least one of the position of a touch, which is applied from the outside, or the intensity (e.g., pressure) of the touch. The input sensing layer ISL may have various suitable configurations, or may be composed of various suitable materials, and is not limited to any one embodiment. For example, the input sensing layer ISL may sense an external input in a capacitive manner. The display panel DP may receive an input signal from the input sensing layer ISL, and may generate an image corresponding to the input signal.

The optical layer OPL may be disposed on an upper side of (e.g., above) the input sensing layer ISL. The optical layer OPL may be disposed on an upper side of (e.g., above) the display panel DP to control reflective light in the display panel DP caused by external light. The optical layer OPL may include, for example, a polarizing plate or a color filter layer.

The lower module LM may include the support layer SPL and the support adhesive layer STP. In some embodiments, the support layer SPL is disposed on a lower side of (e.g., below) the display panel DP. The support layer SPL may be directly disposed on the lower side of (e.g., below) the display panel DP. The support layer SPL may contact the display panel DP. The support layer SPL may protect the display panel DP from an external impact.

The support layer SPL may include a first glass substrate GT1, a second glass substrate GT2, and a resin layer RNL. The first glass substrate GT1, the second glass substrate GT2, and the resin layer RNL may be directly disposed on the lower side of (e.g., below) the display panel DP.

In a display device of the related art, a protection film is directly disposed on a lower side of (e.g., below) a display panel. The protection film is provided to protect the display panel from an external impact. A method of the related art for manufacturing a display device includes providing a glass substrate, as a carrier substrate, on a lower side of (e.g., below) a display panel, removing the provided glass substrate, and providing a protection film.

In the display device ED of some embodiments, the first glass substrate GT1 and the second glass substrate GT2 are directly disposed on the lower side of (e.g., below) the display panel DP, and the first glass substrate GT1 and the second glass substrate GT2 may be carrier substrates provided in a manufacturing step and not removed. Therefore, because a manufacturing method of the display device ED does not include steps of removing a glass substrate and providing a protection film, the manufacturing costs may be reduced, and the manufacturing efficiency may be improved (e.g., increased).

The first glass substrate GT1 and the second glass substrate GT2 may not overlap the folding region FA. The first glass substrate GT1 and the second glass substrate GT2 may be spaced apart in the folding region FA. The first glass substrate GT1 may overlap the first non-folding region NFA1. The second glass substrate GT2 may overlap the second non-folding region NFA2. The resin layer RNL may overlap the folding region FA, the first non-folding region NFA1, and the second non-folding region NFA2.

As used herein, when one element overlaps another element, it means that the one element overlaps the another element in the thickness direction DR3 (e.g., in a plan view). In addition, the overlapping of one element with another element is not only limited to a case in which the one element and the another element have the same area and the same shape, but also includes a case in which the one element and the another element have different areas and/or different shapes. The area refers to the area on a plane.

The support adhesive layer STP may be disposed on a lower side of (e.g., below) the support layer SPL. The support adhesive layer STP may be directly disposed on the lower side of (e.g., below) the support layer SPL. The support adhesive layer STP may be disposed on lower sides of the first glass substrate GT1, the second glass substrate GT2, and the resin layer RNL. The support adhesive layer STP may include a first adhesive layer TP1 and a second adhesive layer TP2. The first adhesive layer TP1 may overlap the first non-folding region NFA1, and the second adhesive layer TP2 may overlap the second non-folding region NFA2. The first adhesive layer TP1 and the second adhesive layer TP2 may be spaced apart in the folding region FA.

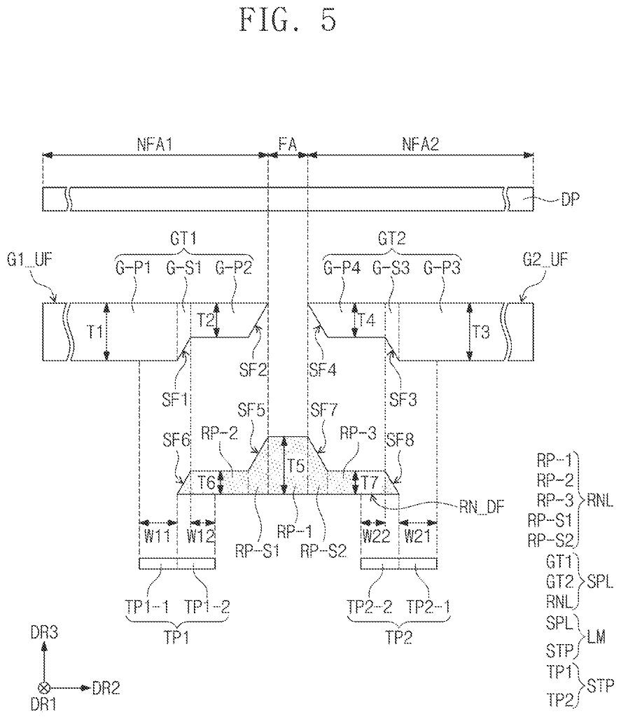

FIG. 5 is a cross-sectional view showing the display panel DP and the lower module LM, according to some embodiments of the inventive concept. In FIG. 5, for the convenience of explanation, the display panel DP and the lower module LM are illustrated separately, and other components of the display device ED are omitted.

Referring to FIG. 5, the first glass substrate GT1 may include a first portion G-P1 and a second portion G-P2 which are different in thickness. A second thickness T2 of the second portion G-P2 may be less than a first thickness T1 of the first portion G-P1. For example, the first thickness T1 may be about 200 μm. However, this is only exemplary, and embodiments of the inventive concept are not limited thereto.

The second thickness T2 may be less than about 50% of the first thickness T1. For example, the second thickness T2 may be about 25% or more of the first thickness T1. When the second thickness is about 50% or more of the first thickness, as the second thickness increases, the resin layer may not absorb an external impact. A portion (e.g., a second resin portion RP-2) of the resin layer RNL may be disposed on a lower side of (e.g., below) the second portion G-P2. When the second thickness is large, a portion of the resin layer is disposed with a small thickness, so that the resin layer may not absorb an external impact, resulting in causing damage to the display panel, the glass substrate, and the like. In some embodiments, the first glass substrate GT1 including the second portion G-P2 satisfying the aforementioned range of the second thickness T2 exhibits excellent reliability.

The first portion G-P1 may be spaced apart from the folding region FA with the second portion G-P2 interposed therebetween. The first portion G-P1 may be adjacent to the outer side of the display device ED (see, e.g., FIG. 1A), and the second portion G-P2 may be adjacent to the inner side of the display device ED (see, e.g., FIG. 1A).

The first glass substrate GT1 may further include a fifth portion G-S1 having a first inclined surface SF1 between the first portion G-P1 and the second portion G-P2. The first portion G-P1, the second portion G-P2, and the fifth portion G-S1 may be integrally formed as one unitary integral component. The fifth portion G-S1 may have a first thickness T1 on one side adjacent to the first portion G-P1 and a second thickness T2 on the other side adjacent to the second portion G-P2.

The second portion G-P2 may include a second inclined surface SF2. An upper surface G1_UF of the first glass substrate GT1 may be a flat surface. In the first glass substrate GT1, an angle formed between the second inclined surface SF2 and the upper surface G1_UF may be greater than 0° to less than 90°.

The second glass substrate GT2 may include a third portion G-P3 and a fourth portion G-P4 which are different in thickness. A fourth thickness T4 of the fourth portion G-P4 may be less than a third thickness T3 of the third portion G-P3. For example, the third thickness T3 may be about 200 μm. However, this is only exemplary, and embodiments of the inventive concept are not limited thereto.

The fourth thickness T4 may be less than about 50% of the third thickness T3. For example, the fourth thickness T4 may be about 25% or more of the third thickness T3. When the fourth thickness is about 50% or more of the third thickness, as the thickness of the fourth portion increases, the resin layer may not absorb an external impact. A portion (e.g., a third resin portion RP-3) of the resin layer RNL may be disposed on a lower side of (e.g., below) the fourth portion G-P4. When the fourth thickness is large, a portion of the resin layer is disposed with a small thickness, so that the resin layer may not absorb an external impact, resulting in causing damage to the display panel, the glass substrate, and the like. In some embodiments, the second glass substrate GT2 including the fourth portion G-P4 satisfying the aforementioned range of the fourth thickness T4 exhibits excellent reliability.

The third portion G-P3 may be spaced apart from the folding region FA with the fourth portion G-P4 interposed therebetween. The third portion G-P3 may be adjacent to the outer side of the display device ED (see, e.g., FIG. 1A), and the fourth portion G-P4 may be adjacent to the inner side of the display device ED (see, e.g., FIG. 1A).

The second glass substrate GT2 may further include a sixth portion G-S3 having a third inclined surface SF3 between the third portion G-P3 and the fourth portion G-P4. The third portion G-P3, the fourth portion G-P4, and the sixth portion G-S3 may be integrally formed as one unitary integral component. The sixth portion G-S3 may have a fourth thickness T4 on one side adjacent to the fourth portion G-P4 and a third thickness T3 on the other side adjacent to the third portion G-P3.

The fourth portion G-P4 may include a fourth inclined surface SF4. An upper surface G2_UF of the second glass substrate GT2 may be a flat surface. In the second glass substrate GT2, an angle formed between the fourth inclined surface SF4 and the upper surface G2_UF may be greater than 0° to less than 90°.

The first glass substrate GT1 and the second glass substrate GT2 may be etched to have a step. For example, the first glass substrate GT1 and the second glass substrate GT2 may be wet-etched by an etchant. Accordingly, the first glass substrate GT1 may include the first and second portions G-P1 and G-P2 having different thicknesses T1 and T2, and the second glass substrate GT2 may include the third and fourth portions G-P3 and G-P4 having different thicknesses T3 and T4. In addition, the first and second glass substrates GT1 and GT2 formed by etching may include the first to fourth inclined surfaces SF1, SF2, SF3, and SF4.

The resin layer RNL may be disposed between the first glass substrate GT1 and the second glass substrate GT2. The resin layer RNL may be disposed while filling a space between the first glass substrate GT1 and the second glass substrate GT2. The resin layer RNL may be disposed while filling a space between the first portion G-P1 of the first glass substrate GT1 and the third portion G-P3 of the second glass substrate GT2. In addition, the resin layer RNL may be disposed while filling a space between the second portion G-P2 of the first glass substrate GT1 and the fourth portion G-P4 of the second glass substrate GT2.

The resin layer RNL may include a thermosetting resin or a photo-curable resin. The resin layer RNL may be formed by providing a liquid resin composition between the first glass substrate GT1 and the second glass substrate GT2, and then curing the provided resin composition.

For example, the resin layer RNL may include at least one of an acrylic resin, a silicone-based resin, or an allyl-based resin. However, this is only exemplary, and the material included in the resin layer RNL is not limited thereto.

At a temperature of 25° C., the Young's modulus of the resin layer RNL may be 100 MPa or less. For example, at a temperature of 25° C., the Young's modulus of the resin layer RNL may be 1 MPa or greater. A resin layer having a Young's modulus of greater than 100 MPa at a temperature of 25° C. has a relatively large Young's modulus, and thus, is not easily folded and unfolded, repeatedly. In some embodiments, the resin layer RNL having a Young's modulus of 100 MPa or less at a temperature of 25° C. is easily folded and unfolded, repeatedly. Accordingly, the display device ED (see, e.g., FIG. 3) including the resin layer RNL having a Young's modulus of 100 MPa or less at a temperature of 25° C. may exhibit excellent reliability.

The resin layer RNL may include a first resin portion RP-1, a second resin portion RP-2, and a third resin portion RP-3. The first resin portion RP-1 may overlap the folding region FA. The first resin portion RP-1 may not overlap the first and second glass substrates GT1 and GT2. The second resin portion RP-2 may overlap the first non-folding region NFA1. The second resin portion RP-2 may overlap the second portion G-P2 of the first glass substrate GT1, and may not overlap the first portion G-P1 of the first glass substrate GT1. The third resin portion RP-3 may overlap the second non-folding region NFA2. The third resin portion RP-3 may overlap the fourth portion G-P4 of the second glass substrate GT2, and may not overlap the third portion G-P3 of the second glass substrate GT2. A fifth thickness T5 of the first resin portion RP-1 may be greater than a sixth thickness T6 of the second resin portion RP-2 and a seventh thickness T7 of the third resin portion RP-3.

The fifth thickness T5 of the first resin portion RP-1 may be substantially the same as the first thickness T1 of the first portion G-P1 of the first glass substrate GT1. The sum of the sixth thickness T6 of the second resin portion RP-2 and the second thickness T2 of the second portion G-P2 of the first glass substrate GT1 may be substantially the same as the fifth thickness T5 of the first resin portion RP-1. The fifth thickness T5 of the first resin portion RP-1 may be substantially the same as the third thickness T3 of the third portion G-P3 of the second glass substrate GT2. The sum of the seventh thickness T7 of the third resin portion RP-3 and the fourth thickness T4 of the fourth portion G-P4 of the second glass substrate GT2 may be substantially the same as the fifth thickness T5 of the first resin portion RP-1. As used herein, being substantially the same includes not only a case in which physical values are the same, but also a case in which there is a difference within an error range in a process.

In addition, the resin layer RNL may include a fourth resin portion RP-S1 disposed between the first resin portion RP-1 and the second resin portion RP-2 and a fifth resin portion RP-S2 disposed between the first resin portion RP-1 and the third resin portion RP-3. The fourth resin portion RP-S1 may include a fifth inclined surface SF5. The fifth resin portion RP-S2 may include a seventh inclined surface SF7.

The resin layer RNL may contact the first and second glass substrates GT1 and GT2. The fifth inclined surface SF5 of the resin layer RNL may contact the second inclined surface SF2 of the first glass substrate GT1. The seventh inclined surface SF7 of the resin layer RNL may contact the fourth inclined surface SF4 of the second glass substrate GT2.

The second resin portion RP-2 may include a sixth inclined surface SF6. The sixth inclined surface SF6 of the resin layer RNL may contact the first inclined surface SF1 of the first glass substrate GT1. A lower surface RN_DF of the resin layer RNL may be a flat surface. In the resin layer RNL, an angle formed between the sixth inclined surface SF6 and the lower surface RN_DF may be greater than 0° to less than 90°. The third resin portion RP-3 may include an eighth inclined surface SF8. The eighth inclined surface SF8 of the resin layer RNL may contact the third inclined surface SF3 of the second glass substrate GT2. In the resin layer RNL, an angle formed between the eighth inclined surface SF8 and the lower surface RN_DF may be greater than 0° to less than 90°.

The support adhesive layer STP may include the first adhesive layer TP1 and the second adhesive layer TP2. The first adhesive layer TP1 and the second adhesive layer TP2 may be spaced apart in the second direction DR2. At least a portion of the first adhesive layer TP1 and the second adhesive layer TP2 may not overlap the folding region FA. At least a portion of the first adhesive layer TP1 and the second adhesive layer TP2 may not overlap the first resin portion RP-1.

The first adhesive layer TP1 may include a first region TP1-1 and a second region TP1-2. The first region TP1-1 may overlap the first glass substrate GT1, and may not overlap the resin layer RNL. The first region TP1-1 may overlap the first portion G-P1 of the first glass substrate GT1. The first portion G-P1 of the first glass substrate GT1 may be directly disposed on an upper side of (e.g., above) the first region TP1-1. The first region TP1-1 may not overlap the folding region FA (e.g., may not overlap in a plan view).

The second region TP1-2 may overlap the resin layer RNL. The second region TP1-2 may overlap the second resin portion RP-2 of the resin layer RNL. The second resin portion RP-2 may be disposed on an upper side of (e.g., above) the second region TP1-2, and the fifth portion G-S1 and the second portion G-P2 of the first glass substrate GT1 may be disposed on an upper side of (e.g., above) the second resin portion RP-2. A portion of the second region TP1-2 may overlap the folding region FA.

The second adhesive layer TP2 may include a third region TP2-1 and a fourth region TP2-2. The third region TP2-1 may overlap the second glass substrate GT2, and may not overlap the resin layer RNL. The third region TP2-1 may overlap the third portion G-P3 of the second glass substrate GT2. The third portion G-P3 of the second glass substrate GT2 may be directly disposed on an upper side of (e.g., above) the third region TP2-1. The third region TP2-1 may not overlap the folding region FA.

The fourth region TP2-2 may overlap the resin layer RNL. The fourth region TP2-2 may overlap the third resin portion RP-3 of the resin layer RNL. The third resin portion RP-3 may be disposed on an upper side of (e.g., above) the fourth region TP2-2, and the sixth portion G-S3 and the fourth portion G-P4 of the second glass substrate GT2 may be disposed on an upper side of (e.g., above) the third resin portion RP-3. A portion of the fourth region TP2-2 may overlap the folding region FA.

The support adhesive layer STP including the first to fourth regions TP1-1, TP1-2, TP2-1, and TP2-2 overlapping the glass substrates GT1 and GT2 or the resin layer RNL may bind the glass substrates GT1 and GT2 and the resin layer RNL together. The first adhesive layer TP1 may bind the first glass substrate GT1 and the resin layer RNL together. The second adhesive layer TP2 may bind the second glass substrate GT2 and the resin layer RNL together. Accordingly, the support adhesive layer STP may improve shear properties (e.g., increase elastic shear stiffness) of the support layer SPL.

In the second direction DR2, a first width W11 of the first region TP1-1 of the first adhesive layer TP1 may be about 450 μm or greater. In the second direction DR2, the first width W11 of the first region TP1-1 of the first adhesive layer TP1 may be less than or equal to the width of the first portion G-P1 of the first glass substrate GT1. When the first width of the first region is less than about 450 μm, the first adhesive layer does not stably bind the first glass substrate and the resin layer together, and the support layer exhibits low shear properties (such as low elastic shear stiffness). Accordingly, when an external impact is applied to the display device, the first glass substrate and the resin layer may be delaminated. The first adhesive layer TP1 in which the first width W11 of the first region TP1-1 is about 450 μm or greater may stably bind the first glass substrate GT1 and the resin layer RNL together, so that the support layer SPL may exhibit excellent shear properties (such as high elastic shear stiffness).

In the second direction DR2, a second width W12 in the second region TP1-2 of the first adhesive layer TP1 may be about 450 μm or greater. The second width W12 may be the width of a region overlapping the second portion G-P2 of the first glass substrate GT1 in the second region TP1-2. In the second direction DR2, the second width W12 may be obtained by excluding the width of a region overlapping the fifth portion G-S1 of the first glass substrate GT1 from the total width of the second region TP1-2. The first adhesive layer TP1 in which the second width W12 of a region overlapping the second portion G-P2 of the first glass substrate GT1 is about 450 μm or greater may stably bind the first glass substrate GT1 and the resin layer RNL together, and thus, may exhibit excellent reliability.

In the second direction DR2, a third width W21 of the third region TP2-1 of the second adhesive layer TP2 may be about 450 μm or greater. In the second direction DR2, the third width W21 of the third region TP2-1 of the second adhesive layer TP2 may be less than or equal to the width of the third portion G-P3 of the second glass substrate GT2. When the third width of the third region is less than about 450 μm, the second adhesive layer does not stably bind the second glass substrate and the resin layer together. Accordingly, when an external impact is applied to the display device, the second glass substrate and the resin layer may be delaminated. The second adhesive layer TP2 in which the third width W21 of the third region TP2-1 is about 450 μm or greater may stably bind the second glass substrate GT2 and the resin layer RNL together to exhibit excellent reliability.

In the second direction DR2, a fourth width W22 of the fourth region TP2-2 of the second adhesive layer TP2 may be about 450 μm or greater. The fourth width W22 may be the width of a region overlapping the fourth portion G-P4 of the second glass substrate GT2 in the fourth region TP2-2. In the second direction DR2, the fourth width W22 may be obtained by excluding the width of a region overlapping the sixth portion G-S3 of the second glass substrate GT2 from the total width of the fourth region TP2-2. The second adhesive layer TP2 in which the width W22 of a region overlapping the fourth portion G-P4 of the second glass substrate GT2 is about 450 μm or greater may stably bind the second glass substrate GT2 and the resin layer RNL together, and thus, may exhibit excellent reliability.

At room temperature, the adhesive force of the support adhesive layer STP may be about 3000 gf/in or greater. The room temperature may refer to a temperature between 20° C. and 30° C. A support adhesive layer having an adhesive force of less than 3000 gf/in at room temperature may not stably bind a glass substrate and a resin layer together, so that the glass substrate and resin layer may be delaminated in the event of an external impact. The support adhesive layer STP having an adhesive force of 3000 gf/in or greater at room temperature may stably bind the glass substrates GT1 and GT2 and the resin layer RNL together, and thus, may exhibit excellent reliability.

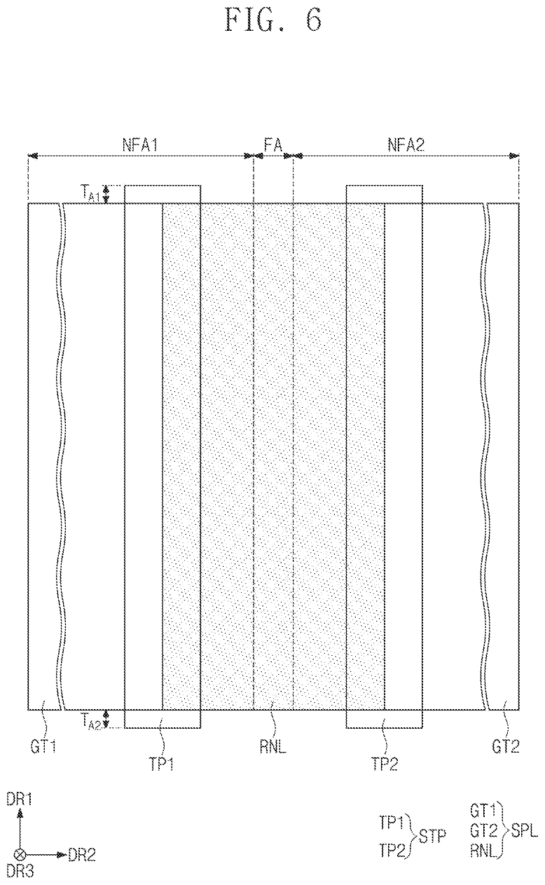

FIG. 6 is a plan view showing the support layer SPL and the support adhesive layer STP, according to some embodiments of the inventive concept. In FIG. 6, for the convenience of explanation, other components of the display device ED are omitted.

Referring to FIG. 6, the first glass substrate GT1 and the second glass substrate GT2 may be spaced apart on a plane. The first glass substrate GT1 and the second glass substrate GT2 may be spaced apart in the second direction DR2. The first glass substrate GT1 and the second glass substrate GT2 may be spaced apart in the second direction DR2 which crosses the first direction DR1 in which the folding axes FX1 and FX2 (see, e.g., FIGS. 1B and 1D) are extended. The first glass substrate GT1 and the second glass substrate GT2 are not integrated, and may be separate components. Because the first glass substrate GT1 and the second glass substrate GT2 are separate components, in the event of an external impact, the first glass substrate GT1 and the second glass substrate GT2 may exhibit a large amount of displacement due to the impact.

In some embodiments, the first glass substrate GT1 and the second glass substrate GT2 include the first to fourth portions G-P1, GP-2, GP-3, and GP-4 (see, e.g., FIG. 5) having different thicknesses T1, T2, T3, and T4 (see, e.g., FIG. 5), and the resin layer RNL is disposed while filling spaces between the first to fourth portions G-P1, GP-2, GP-3, and GP-4 (see, e.g., FIG. 5), so that the contact area of the resin layer RNL for the first and second glass substrates GT1 and GT2 may increase. Because the contact area of the resin layer RNL for the first and second glass substrates GT1 and GT2 increases, the degree of binding of the first and second glass substrates GT1 and GT2 and the resin layer RNL may improve (e.g., increase), and the amount of impact absorbed by the resin layer RNL may increase.

In addition, the support adhesive layer STP overlapping the first and second glass substrates GT1 and GT2 and the resin layer RNL more stably binds the first and second glass substrates GT1 and GT2 and the resin layer RNL together, and thus, may reduce the amount of displacement of the first glass substrate GT1 and the amount of displacement of the second glass substrate GT2 due to an external impact. Accordingly, in the display device ED of some embodiments, the first glass substrate GT1, the second glass substrate GT2, and the resin layer RNL are stably bound in the event of an external impact, so that excellent reliability may be exhibited.

In the first direction DR1 in which the first and second folding axes FX1 and FX2 (see, e.g., FIGS. 1B and 1D) are extended, differences T_{A1} and T_{A2} between the length of the first glass substrate GT1 and the length of the first adhesive layer TP1 may be 0 μm or greater. That is, in the first direction DR1, the length of the first adhesive layer TP1 may be greater than or equal to the length of the first glass substrate GT1. In the first direction DR1, when the length of the first adhesive layer is less than the length of the first glass substrate, the first adhesive layer may not stably bind the first glass substrate and the resin layer together. In some embodiments, in the first direction DR1, the first adhesive layer TP1 whose length is greater than or equal to the length of the first glass substrate GT1 stably binds the first glass substrate GT1 and the resin layer RNL, and thus, may exhibit excellent reliability.

The description of the length of the first glass substrate GT1 and the length of the first adhesive layer TP1 may be equally applied to the length of the second glass substrate GT2 and the length of the second adhesive layer TP2. That is, in the first direction DR1, the length of the second adhesive layer TP2 may be greater than or equal to the length of the second glass substrate GT2. In some embodiments, in the first direction DR1, the second adhesive layer TP2 whose length is greater than or equal to the length of the second glass substrate GT2 stably binds the second glass substrate GT2 and the resin layer RNL together, and thus, may exhibit excellent reliability.

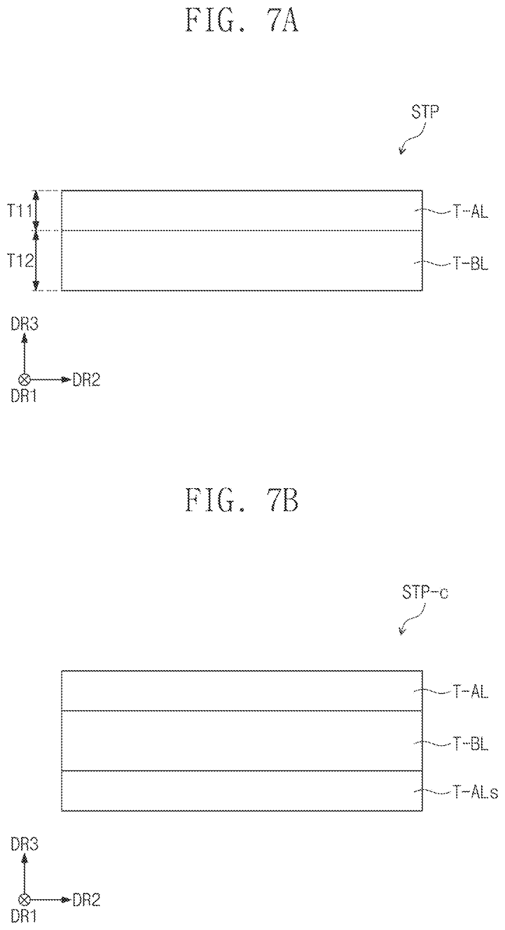

FIG. 7A is a cross-sectional view showing the support adhesive layer STP according to some embodiments of the inventive concept. FIG. 7B is a cross-sectional view showing a support adhesive layer STP-c according to some other embodiments of the inventive concept. The contents of the support adhesive layers STP and STP-c described with reference to FIGS. 7A and 7B may be equally applied to the first and second adhesive layers TP1 and TP2.

The support adhesive layer STP may not include a pressure sensitive adhesive (PSA). Because the pressure sensitive adhesive cannot stably bind a glass substrate and a resin layer together, in the event of an external impact, the glass substrate and the resin layer may be delaminated. The support adhesive layer STP may include an adhesive with high adhesive force. For example, the support adhesive layer STP may include a single-sided tape or a double-sided tape.

Referring to FIG. 7A, the support adhesive layer STP may include a base portion T-BL and an adhesive portion T-AL disposed on an upper side of (e.g., above) the base portion T-BL. FIG. 7A may show a single-sided tape.

The adhesive portion T-AL may contact the first glass substrate GT1, the second glass substrate GT2, and the resin layer RNL. For example, the adhesive portion T-AL may include at least one of a silicon-based resin, a urethane-based resin, an acrylic resin, an isocyanate-based resin, a polyvinyl alcohol-based resin, a gelatin-based resin, a vinyl-based resin, a latex-based resin, a polyester-based resin, or a water-based polyester-based resin. A thickness T11 of the adhesive portion T-AL may be about 25 μm. However, this is only exemplary, and the material included in the adhesive portion T-AL and the thickness thereof are not limited thereto.

The base portion T-BL may include at least one of polyethylene terephthalate (PET), polyimide (PI), polycarbonate (PC), polyethylene (PE), polypropylene (PP), polysulfone (PSF), polymethyl methacrylate (PMMA), triacetyl cellulose (TAC), or cycloolefin polymer (COP). For example, the base portion T-BL may include polyethylene terephthalate (PET), and/or the like.

A thickness T12 of the base portion T-BL may be about 50 μm to about 100 μm. When the thickness of a base portion is less than about 50 μm, a glass substrate and a resin layer are not stably bound together, so that the glass substrate and resin layer may be delaminated in the event of an external impact. When the thickness of a base portion is greater than about 100 μm, the thickness of a display device is increased. In some embodiments, the base portion T-BL having the thickness T12 of about 50 μm to about 100 μm stably binds the glass substrates GT1 and GT2 and the resin layer RNL together while maintaining a good thickness (e.g., a desirably low thickness) of the display device ED, so that excellent reliability may be exhibited.

Compared to the support adhesive layer STP of FIG. 7A, there is a difference in that the support adhesive layer STP-c of FIG. 7B further includes a sub-adhesive portion T-ALs. The support adhesive layer STP-c may further include the sub-adhesive portion T-ALs disposed on a lower side of (e.g., below) the base portion T-BL. FIG. 7B may show a double-sided tape.

The sub-adhesive portion T-ALs and the adhesive portion T-AL may include the same material. In some examples, the sub-adhesive portion T-ALs and the adhesive portion T-AL may include different materials. For example, the sub-adhesive portion T-ALs may include at least one of a silicon-based resin, a urethane-based resin, an acrylic resin, an isocyanate-based resin, a polyvinyl alcohol-based resin, a gelatin-based resin, a vinyl-based resin, a latex-based resin, a polyester-based resin, or a water-based polyester-based resin. However, this is only exemplary, and the material included in the sub-adhesive portion T-ALs is not limited thereto. Further, unlike what is illustrated, the base portion T-BL may be omitted.

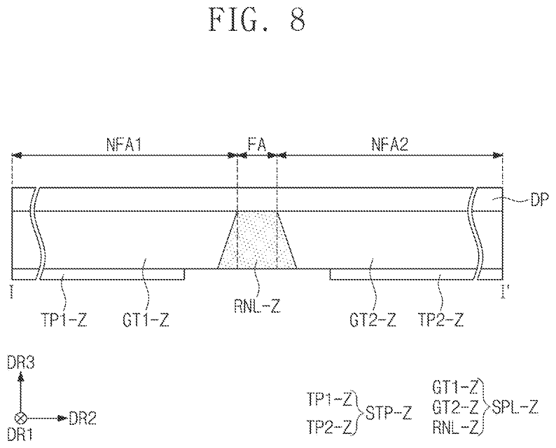

FIG. 8 is a cross-sectional view showing a support layer SPL-Z and a support adhesive layer STP-Z of the related art. In the support layer SPL-Z of the related art, first and second glass substrates GT1-Z and GT2-Z do not include the second and fourth portions G-P2 and G-P4 (see, e.g., FIG. 5) which are different in thickness. That is, in the support layer SPL-Z of the related art, the first and second glass substrates GT1-Z and GT2-Z may not include a step portion.

The support adhesive layer STP-Z of the related art includes a pressure sensitive adhesive, and does not overlap a resin layer RNL-Z. A first adhesive layer TP1-Z of the related art may overlap the first glass substrate GT1-Z, and may not overlap the resin layer RNL-Z. A second adhesive layer TP2-Z of the related art may overlap the second glass substrate GT2-Z, and may not overlap the resin layer RNL-Z. Accordingly, the first and second glass substrates GT1-Z and GT2-Z and the resin layer RNL-Z of the related art may not be stably bound, and in the event of an external impact, the resin layer RNL-Z may be delaminated.

The display device ED according to some embodiments includes the first and second glass substrates GT1 and GT2 including the first to fourth portions G-P1, GP-2, GP-3, and GP-4 having different thicknesses T1, T2, T3, and T4, and the resin layer RNL disposed while filling spaces between the first to fourth portions G-P1, GP-2, GP-3, and GP-4, and the support adhesive layer STP directly disposed on a lower side of (e.g., below) the support layer SPL, and thus, may exhibit excellent shear properties (such as high elastic shear stiffness) in the event of an external impact.

Table 1 below shows the evaluation of the stress of a display panel due to an external impact in Comparative Example 1 and Example 1. Table 1 shows simulation results obtained by applying an impact to a corner portion in the display device of each of Comparative Example 1 and Example 1 and evaluating the stress received by the display panel. The display devices of Comparative Example 1 and Example 1 differ in the support layer and the support adhesive layer. The display device of Comparative Example 1 includes the support layer and the support adhesive layer illustrated in FIG. 8, and the display device of Example 1 is a display device according to some embodiments, which includes the support layer and the support adhesive layer illustrated in FIG. 5.

TABLE 1

| | Comparative Example 1 | Example 1 |
|---|---|---|
| Stress (MPa) | 506 | 37 |

Referring to Table 1, it can be seen that the stress received by the display panel in the display device of Example 1 is very small compared to the display device of Comparative Example 1. The display device of Example 1 is a display device according to some embodiments, which includes first and second glass substrates including regions having different thicknesses, and a resin layer disposed between the first and second glass substrates. In addition, Example includes a support adhesive layer overlapping the first and second glass substrates and the resin layer. Accordingly, the display device of the embodiment may have an increased degree of absorption and dispersion of external impacts in components other than the display panel, so that the stress received by the display panel may be measured to be very small.

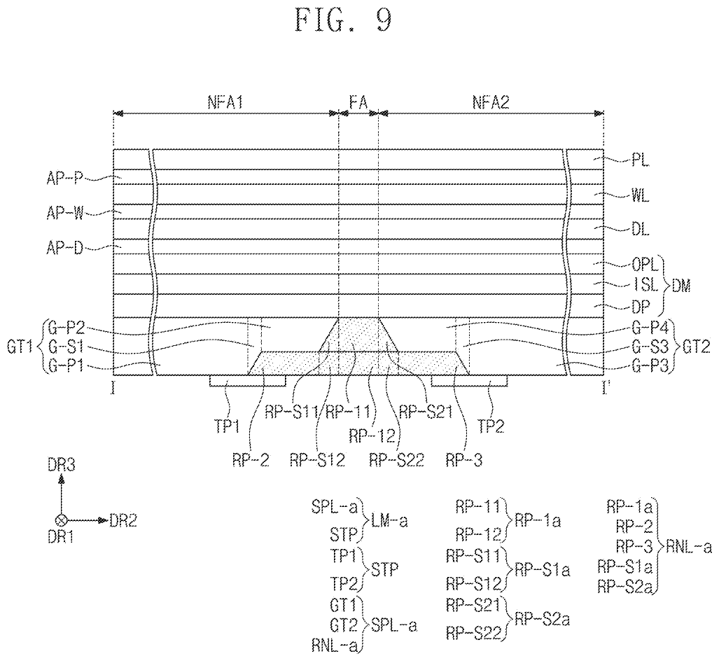

FIG. 9 to. 14 are cross-sectional views showing other embodiments of the inventive concept. Hereinafter, in describing with reference to FIGS. 9 to 14, the same contents as those described with reference to FIG. 1A to FIG. 8 will not be described again, and instead, differences will be mainly described.

A lower module LM-a of FIG. 9 is different from the lower module LM of FIG. 3 in a resin layer RNL-a included in a support layer SPL-a. The resin layer RNL-a may include a first resin portion RP-1a, a second resin portion RP-2, and a third resin portion RP-3. In addition, the resin layer RNL-a may include a fourth resin portion RP-S1a disposed between the first resin portion RP-1a and the second resin portion RP-2 and a fifth resin portion RP-S2a disposed between the first resin portion RP-1a and the third resin portion RP-3.

The first resin portion RP-1a may include a first sub-resin portion RP-11 and a second sub-resin portion RP-12 disposed on a lower side of (e.g., below) the first sub-resin portion RP-11. The first sub-resin portion RP-11 may be directly disposed on a lower side of (e.g., below) the display panel DP. The second sub-resin portion RP-12 may be spaced apart from the display panel DP with the first sub-resin portion RP-11 interposed therebetween.

In the second direction DR2, the first sub-resin portion RP-11 may be disposed between the second portion G-P2 and the fourth portion G-P4. In the second direction DR2, the first sub-resin portion RP-11 may be disposed between the second portion G-P2 and the fourth portion G-P4. In the second direction DR2, the second sub-resin portion RP-12 may be disposed between the first portion G-P1 and the third portion G-P3.

The first sub-resin portion RP-11 and the second sub-resin portion RP-12 may include different materials. For example, each of the first sub-resin portion RP-11 and the second sub-resin portion RP-12 may include at least one of an acrylic resin, a silicon-based resin, or an allyl-based resin. However, this is only exemplary, and embodiments of the inventive concept are not limited thereto.

The Young's modulus of the first sub-resin portion RP-11 and the Young's modulus of the second sub-resin portion RP-12 may be different. For example, the Young's modulus of the first sub-resin portion RP-11 may be greater than the Young's modulus of the second sub-resin portion RP-12. In some examples, the Young's modulus of the first sub-resin portion RP-11 may be smaller than the Young's modulus of the second sub-resin portion RP-12.

The Young's modulus of the first sub-resin portion RP-11 may be different from the Young's modulus of the second resin portion RP-2 and the Young's modulus of the third resin portion RP-3. The Young's modulus of the second sub-resin portion RP-12 may be the same as the Young's modulus of the second resin portion RP-2 and the Young's modulus of the third resin portion RP-3.

The fourth resin portion RP-S1a may include a third sub-resin portion RP-S11 and a fourth sub-resin portion RP-S12 disposed on a lower side of (e.g., below) the third sub-resin portion RP-S11. The third sub-resin portion RP-S11 may be extended from one side of the first sub-resin portion RP-11. The fourth sub-resin portion RP-S12 may be extended from one side of the second sub-resin portion RP-12.

The fifth resin portion RP-S2a may include a fifth sub-resin portion RP-S21 and a sixth sub-resin portion RP-S22 disposed on a lower side of (e.g., below) the fifth sub-resin portion RP-S21. The fifth sub-resin portion RP-S21 may be extended from the other side of the first sub-resin portion RP-11. The sixth sub-resin portion RP-S22 may be extended from the other side of the second sub-resin portion RP-12.

The first sub-resin portion RP-11, the third sub-resin portion RP-S11, and the fifth sub-resin portion RP-S21 may have a shape of a single body. The second sub-resin portion RP-12, the fourth sub-resin portion RP-S12, the sixth sub-resin portion RP-S22, the second resin portion RP-2, and the third resin portion RP-3 may have a shape of a single body.

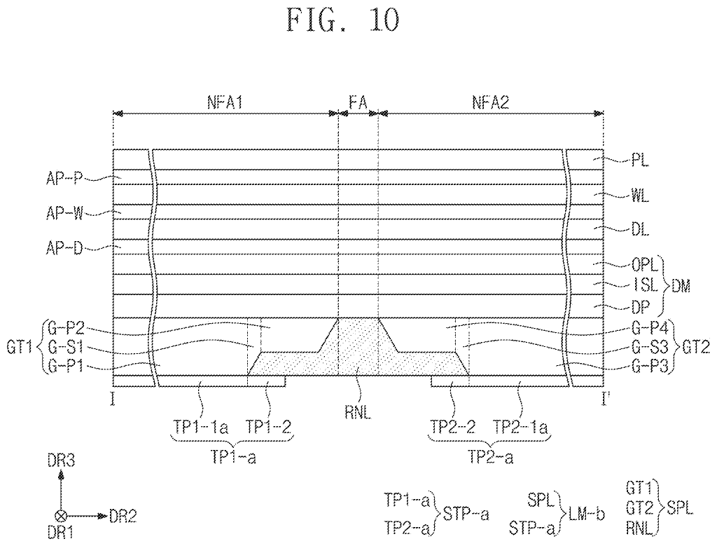

A lower module LM-b of FIG. 10 is different from the lower module LM of FIG. 5 in a support adhesive layer STP-a. Referring to FIG. 10, in the support adhesive layer STP-a, a first region TP1-1a of a first adhesive layer TP1-a may entirely overlap the first portion G-P1 of the first glass substrate GT1. In the second direction DR2, the width of the first region TP1-1a of the first adhesive layer TP1-a and the width of the first portion G-P1 of the first glass substrate GT1 may be the same. A third region TP2-1a of a second adhesive layer TP2-a may entirely overlap the third portion G-P3 of the second glass substrate GT2. In the second direction DR2, the width of the third region TP2-1a of the second adhesive layer TP2-a and the width of the third portion G-P3 of the second glass substrate GT2 may be the same.

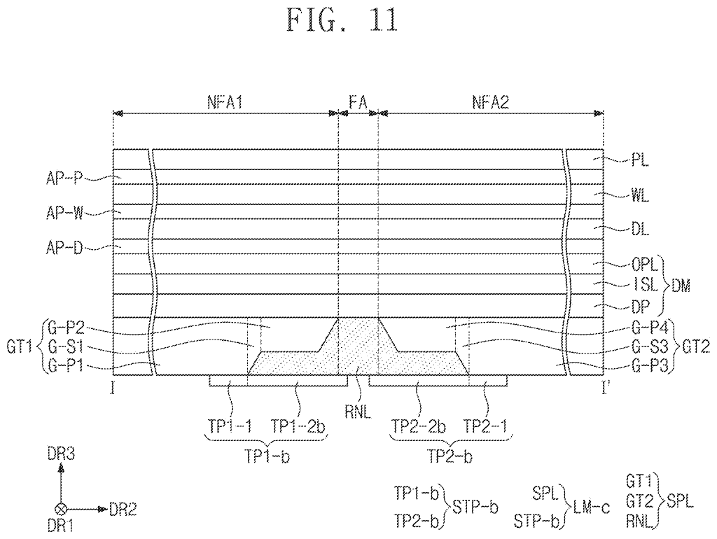

A lower module LM-c of FIG. 11 is different from the lower module LM of FIG. 5 in a support adhesive layer STP-b. Referring to FIG. 11, a portion of the support adhesive layer STP-b may overlap the folding region FA. A portion of a second region TP1-2b of a first adhesive layer TP1-b may overlap the folding region FA. A portion of a fourth region TP2-2b of a second adhesive layer TP2-b may overlap the folding region FA. The second region TP1-2b of the first adhesive layer TP1-b and the fourth region TP2-2b of the second adhesive layer TP2-b may be spaced apart in the folding region FA.

Compared to the lower module LM of FIG. 5, there is a difference in that a lower module LM-d of FIG. 12 further includes a metal layer ML. In some embodiments, the metal layer ML is disposed on a lower side of (e.g., below) the support adhesive layer STP. The metal layer ML may not overlap the folding region FA. The metal layer ML may include a metal having relatively high rigidity. For example, the metal layer ML may include stainless steel. The metal layer ML may stably bind the first and second glass substrates GT1 and GT2 and the resin layer RNL together, and thus, may improve shear properties (e.g., increase elastic shear stiffness) of the display device ED. When the lower module LM-d includes the metal layer ML, the base portion T-BL (see, e.g., FIG. 7A) of the support adhesive layer STP may be omitted.

The metal layer ML may include a first metal layer ML1 and a second metal layer ML2 spaced apart in the folding region FA. The first metal layer ML1 may be disposed on a lower side of (e.g., below) the first adhesive layer TP1. The second metal layer ML2 may be disposed on a lower side of (e.g., below) the second adhesive layer TP2.

The first metal layer ML1 may include a first metal region MA1-1 overlapping the first portion G-P1 of the first glass substrate GT1 and a second metal region MA1-2 overlapping the resin layer RNL. The first metal region MA1-1 may overlap the first region TP1-1 of the first adhesive layer TP1. The second metal region MA1-2 may overlap the second region TP1-2 of the first adhesive layer TP1. The second metal region MA1-2 may overlap the second and fifth portions G-P2 and G-S1 of the first glass substrate GT1.

The second metal layer ML2 may include a third metal region MA2-1 overlapping the third portion G-P3 of the second glass substrate GT2 and a fourth metal region MA2-2 overlapping the resin layer RNL. The third metal region MA2-1 may overlap the third region TP2-1 of the second adhesive layer TP2. The fourth metal region MA2-2 may overlap the fourth region TP2-2 of the second adhesive layer TP2. The fourth metal region MA2-2 may overlap the fourth and sixth portions G-P4 and G-S3 of the second glass substrate GT2.

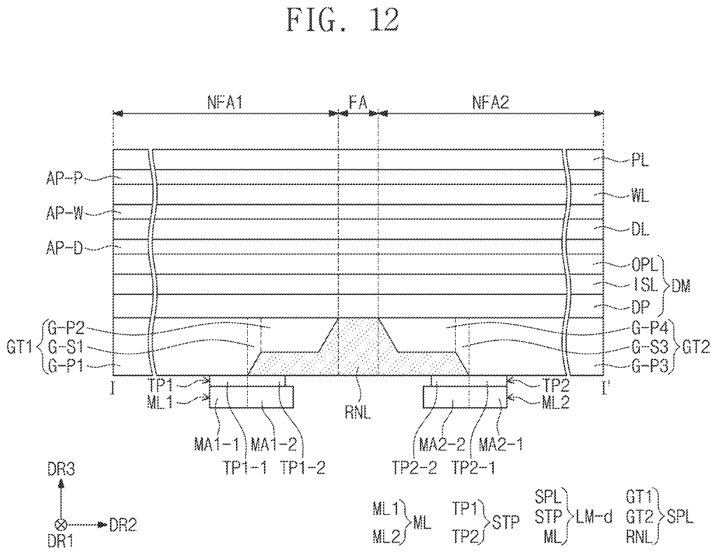

A lower module LM-e FIG. 13 is different from the lower module LM of FIG. 5 in the resin layer RNL-a and the metal layer ML. The lower module LM-e of FIG. 13 may include the resin layer RNL-a described with reference to FIG. 9 and the metal layer ML described with reference to FIG. 12. The contents described with reference to FIG. 9 may be equally applied to the resin layer RNL-a of FIG. 13. The contents described with reference to FIG. 12 may be equally applied to the metal layer ML of FIG. 13.

Table 2 below shows the evaluation of the stress of a display panel due to an external impact in Comparative Examples and Experimental Examples. Table 2 shows simulation results obtained by applying an impact to a corner portion in the display device of each of Comparative Examples and Experimental Examples and evaluating the stress received by the display panel. The display device of each of Comparative Examples and Experimental Examples includes the display panel, the support layer, and the support adhesive layer illustrated in FIG. 8.

In Comparative Example 3, the thickness of a polyimide layer constituting a base layer of the display panel is about 40 μm. In Comparative Example 1, Comparative Example 2, and Experimental Examples, the thickness of a polyimide layer constituting a base layer of the display panel is about 16.4 μm. The display device of Comparative Example 1 is the same as the display device of Comparative Example 1 of Table 1 above.

In the display device of each of Comparative Examples 1 to 3, the lower module does not include a metal layer and a cushion layer, which is different from that of Experimental Examples. In the display device of Experimental Example, the lower module includes stainless steel having a thickness of about 30 μm as a metal layer, and includes a cushion layer having a thickness of about 100 μm. Further, it was confirmed that the resin layer was delaminated in the display device of Comparative Example 1.

TABLE 2

| | Comparative | Comparative | Comparative | Experimental |
|---|---|---|---|---|
| | Example 1 | Example 2 | Example 3 | Example |
| Stress (MPa) | 506 | 439 | 325 | 228 |

Referring to Table 2, it can be seen that the stress received by the display panel in the display device of Experimental Example was reduced compared to the display device of each of Comparative Examples 1 to 3. Compared to the display device of Comparative Example 3, in which the thickness of the base layer of the display panel increased, it can be seen that the stress received by the display panel in the display device of Experimental Example was reduced. It is determined that because the display device of Experimental Example includes a metal layer, the glass substrate and the resin layer are stably bound, thereby exhibiting excellent shear properties (such as high elastic shear stiffness). Therefore, in some embodiments, it is determined that a display device including a metal layer disposed on a lower side of (e.g., below) a support layer will exhibit excellent shear properties (such as high elastic shear stiffness).

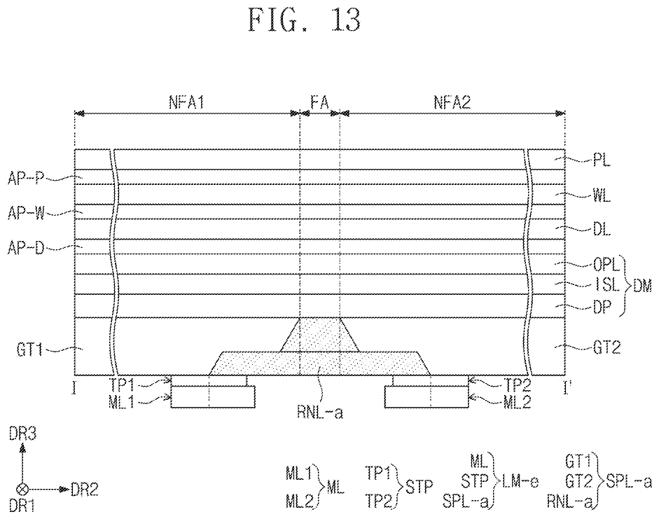

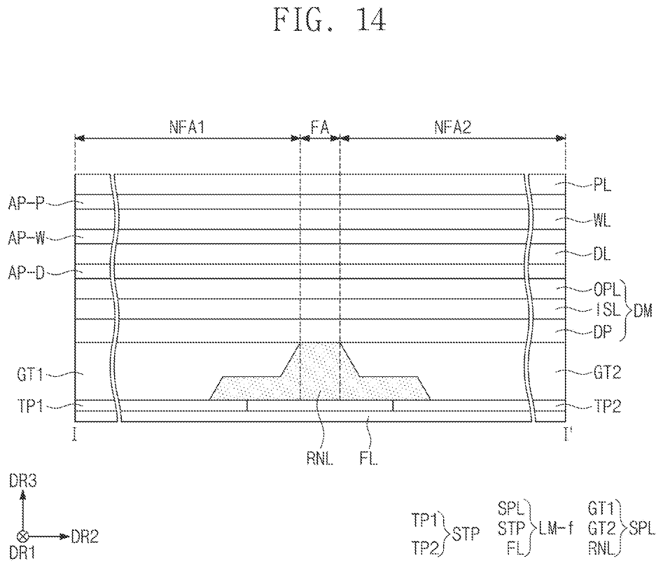

Compared to the lower module LM of FIG. 5, there is a difference in that a lower module LM-f of FIG. 14 further includes a polymer film FL. Referring to FIG. 14, the polymer film FL may be directly disposed on a lower side of (e.g., below) the support adhesive layer STP.

The polymer film FL may overlap the folding region FA, the first non-folding region NFA1, and the second non-folding region NFA2. The polymer film FL may entirely overlap the support layer SPL. The polymer film FL entirely overlapping the support layer SPL may stably bind the first and second glass substrates GT1 and GT2 and the resin layer RNL together, and thus, may improve shear properties (e.g., increase elastic shear stiffness) of the display device ED.

The polymer film FL may include a flexible polymer material. For example, the polymer film FL may include at least one of polyethylene terephthalate (PET) or polyimide (PI). However, this is only exemplary, and the material included in the polymer film FL is not limited thereto.

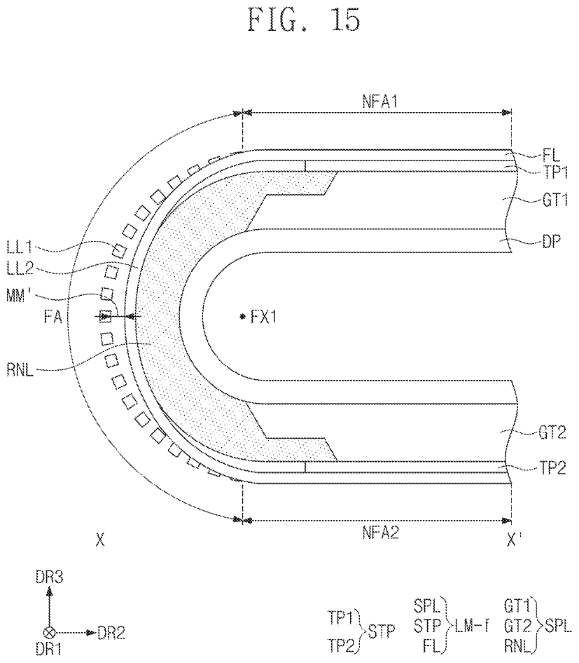

FIG. 15 is a cross-sectional view showing a portion corresponding to the line X-X′ of FIG. 1C, according to some embodiments of the inventive concept. In FIG. 15, for the convenience of explanation, other components of the display device ED are omitted, and only the display panel DP and the lower module LM-f are illustrated. In addition, FIG. 15 shows the lower module LM-f and the display panel DP of FIG. 14, and is a view showing the display panel DP in a folded state.

Referring to FIG. 15, when the display panel DP is in a folded state, the polymer film FL may also be folded. When the display panel DP is in a folded state, at least a portion of the polymer film FL may contact the resin layer RNL.

In FIG. 15, LL1 shows a folding portion of the polymer film FL overlapping the folding region FA in a state in which the support adhesive layer STP is provided as a single adhesive layer without including the first and second adhesive layers TP1 and TP2, and LL2 shows a folding portion of the polymer film FL in a state in which there is the support adhesive layer STP including the first and second adhesive layers TP1 and TP2. Compared to the folding portion LL1 of the polymer film FL in the absence of the support adhesive layer STP, the folding portion LL2 of the polymer film FL in the presence of the support adhesive layer STP may be moved by a set or predetermined distance MM′ in the second direction DR2. The folding portion LL2 of the polymer film FL in the presence of the support adhesive layer may contact the resin layer RNL. Accordingly, during a folding operation, the strain of the polymer film FL may be relaxed. Because the support adhesive layer STP is separated into the first and second adhesive layers TP1 and TP2 and provided, the strain of the polymer film FL may be relaxed during the folding operation.

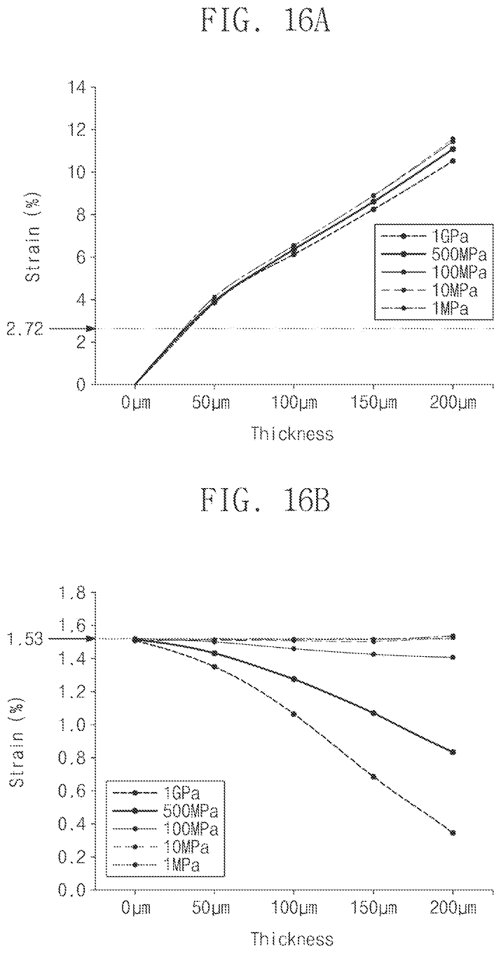

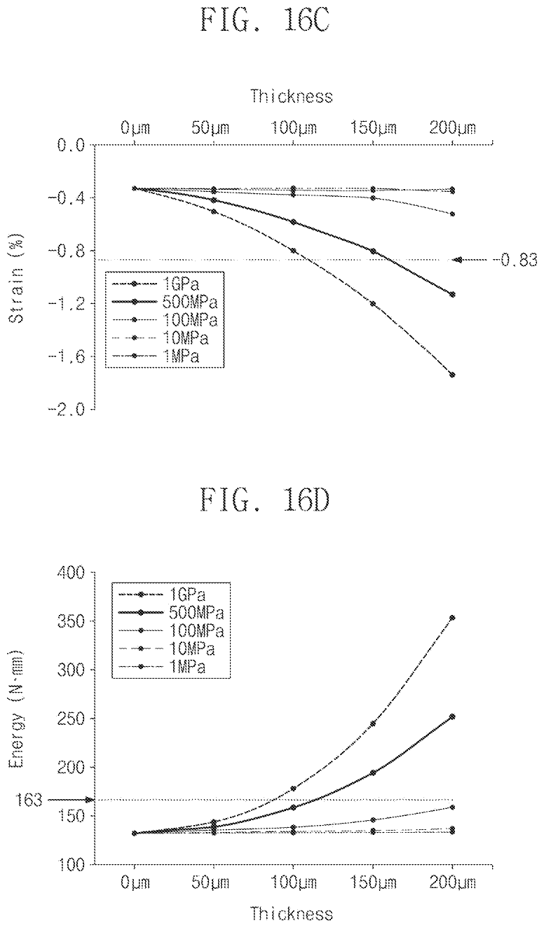

FIGS. 16A to 16C are graphs showing strains as measured according to the Young's modulus and thickness of a resin layer in a display device including the resin layer. The resin layer include an acrylic resin. 1 MPa, 10 MPa, 100 MPa, 500 MPa, and 1 GPa are the Young's modulus of the resin layer. Hereinafter, a display device including a resin layer having a Young's modulus of 1 MPa is referred to as Experimental Example A1, a display device including a resin layer having a Young's modulus of 10 MPa is referred to as Experimental Example A2, and a display device including a resin layer having a Young's modulus of 100 MPa is referred to as Experimental Example A3. A display device including a resin layer having a Young's modulus of 500 MPa is referred to as Comparative Example B1, and a display device including a resin layer having a Young's modulus of 1 GPa is referred to as Comparative Example B2.

FIG. 16A is a graph showing the strain measured on a lower surface of a support layer, and about 2.72% of the strain on the lower surface of the support layer is determined to be a value that maintains reliability. Referring to FIG. 16A, it can be seen that the display device of each of Experimental Examples A1 to A3, Comparative Example B1, and Comparative Example B2 has a similar level of strain measured on the lower surface of the support layer.

FIG. 16B is a graph showing the strain measured on a lower surface of a display panel, and specifically, is a graph showing the strain measured on a base layer. About 1.53% of the strain on the base layer is determined to be a value that maintains reliability. Referring to FIG. 16B, it can be seen that when the thickness of the resin layer increases, the display device of each of Experimental Examples A1 to A3 maintains a strain close to 1.53%. It can be seen that when the thickness of the resin layer increases, the display device of each of Comparative Examples B1 and B2 has a decreased strain.

FIG. 16C is a graph showing the strain measured on an upper surface of a display panel, and specifically, is a graph showing the strain measured on an encapsulation layer. About −0.83% of the strain on the encapsulation layer is determined to be a value that maintains reliability. Referring to FIG. 16C, it can be seen that when the thickness of the resin layer increases, the display device of each of Experimental Examples A1 to A3 maintains a certain level of strain. It can be seen that when the thickness of the resin layer increases, the display device of each of Comparative Examples B1 and B2 has a decreased strain.

FIG. 16D shows elastic energy as measured according to the Young's modulus and thickness of a resin layer in a display device including the resin layer. The resin layer include an acrylic resin. 1 MPa, 10 MPa, 100 MPa, 500 MPa, and 1 GPa are the Young's modulus of the resin layer, and as described with reference to FIGS. 16A to 16C, Experimental Examples A1 to A3, Comparative Example B1, and Comparative Example B2 will be referred to and described. The elastic energy is for confirming the reaction force of the resin layer during folding, and about 163 Nmm is determined to be a value that maintains reliability. Referring to FIG. 16D, it can be seen that when the thickness of the resin layer increases, the elastic energy of the display device of each of Comparative Example B1 and Comparative Example B2 sharply increases, and folding is not easy. It can be seen that when the thickness of the resin layer increases, the elastic energy of the display device of each of Experimental Examples A1 to A3 is maintained at a good level, and folding is easy.

Summing up the results of FIGS. 16A to 16D, it can be seen that the display device of each of Experimental Examples A1 to A3 in which the Young's modulus of the resin layer is 100 MPa or less exhibits excellent reliability. The display device of each of Experimental Examples A1 to A3 satisfies the Young's modulus range of the resin layer according to some embodiments. In some embodiments, at a temperature of 25° C., the Young's modulus of a resin layer may be 100 MPa or less. Accordingly, it is determined that the display device according to some embodiments including the resin layer having a Young's modulus of 100 MPa or less may be easily folded and may exhibit excellent reliability.

The display device of some embodiments includes a lower module disposed on a lower side of (e.g., below) a display panel. The lower module may include a support layer and a support adhesive directly disposed on a lower side of (e.g., below) the support layer. The support layer may include a first glass substrate, a second glass substrate, and a resin layer. The first glass substrate and the second glass substrate may be spaced apart on a plane, and each of the first glass substrate and the second glass substrate includes regions having different thicknesses, and the resin layer may be disposed while filling spaces between the regions having different thicknesses. The support adhesive layer may overlap the first glass substrate, the second glass substrate, and the resin layer. Accordingly, the first glass substrate, the second glass substrate, and the resin layer are stably bound, so that the display device according to some embodiments may exhibit excellent shear properties (such as high elastic shear stiffness) and reliability.

A display device of some embodiments includes a resin layer disposed while filling a space between first and second glass substrates including regions having different thicknesses, and a support adhesive layer having high adhesive force, and thus, may exhibit excellent shear properties (such as high elastic shear stiffness).

It will be understood that, although the terms “first”, “second”, “third”, etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section discussed below could be termed a second element, component, region, layer or section, without departing from the spirit and scope of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. In addition, it will also be understood that when a layer is referred to as being “between” two layers, it can be the only layer between the two layers, or one or more intervening layers may also be present.

The terminology used herein is for the purpose of describing particular embodiments and is not intended to be limiting of the inventive concept. As used herein, the singular forms “a” and “an” are intended to include the plural forms as well, unless the context clearly indicates otherwise. It will be further understood that the terms “include,” “including,” “comprises,” “comprising,” “has,” “have,” and “having,” when used in this specification, specify the presence of stated features, integers, steps, operations, elements, and/or components, but do not preclude the presence or addition of one or more other features, integers, steps, operations, elements, components, and/or groups thereof.

As used herein, the term “and/or” includes any and all combinations of one or more of the associated listed items. For example, the expression “A and/or B” denotes A, B, or A and B. Expressions such as “one or more of” and “at least one of,” when preceding a list of elements, modify the entire list of elements and do not modify the individual elements of the list. For example, the expression “one or more of A, B, and C,” “at least one of A, B, or C,” “at least one of A, B, and C,” and “at least one selected from the group consisting of A, B, and C” indicates only A, only B, only C, both A and B, both A and C, both B and C, or all of A, B, and C.

Further, the use of “may” when describing embodiments of the inventive concept refers to “one or more embodiments of the inventive concept.” Also, the term “exemplary” is intended to refer to an example or illustration.

It will be understood that when an element or layer is referred to as being “on”, “connected to”, “coupled to”, or “adjacent” another element or layer, it can be directly on, connected to, coupled to, or adjacent the other element or layer, or one or more intervening elements or layers may be present. When an element or layer is referred to as being “directly on,” “directly connected to”, “directly coupled to”, “in contact with”, “in direct contact with”, or “immediately adjacent” another element or layer, there are no intervening elements or layers present.

As used herein, the term “substantially,” “about,” and similar terms are used as terms of approximation and not as terms of degree, and are intended to account for the inherent variations in measured or calculated values that would be recognized by those of ordinary skill in the art.

As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification.

Although the present invention has been described with reference to preferred embodiments of the present invention, it will be understood by those skilled in the art that various suitable modifications and changes in form and details may be made therein without departing from the spirit and scope of the present invention as set forth in the following claims.

Accordingly, the technical scope of the inventive concept is not intended to be limited to the contents set forth in the detailed description of the specification, but is intended to be defined by the appended claims.

What is claimed is:

1. A display device comprising:
a display panel comprising a folding region folded based on a folding axis extended in a first direction, and a first non-folding region and a second non-folding region spaced from one another and having the folding region interposed therebetween;
a support layer below the display panel; and
a support adhesive layer below the support layer,
wherein the support layer comprises:
a first glass substrate comprising a first portion having a first thickness and a second portion having a second thickness less than the first thickness, and overlapping the first non-folding region;
a second glass substrate comprising a third portion having a third thickness and a fourth portion having a fourth thickness less than the third thickness, spaced from the first glass substrate, and overlapping the second non-folding region; and
a resin layer between the first glass substrate and the second glass substrate.

2. The display device of claim 1, wherein the support layer is directly below the display panel.

3. The display device of claim 1, wherein the first glass substrate and the second glass substrate do not overlap the folding region.

4. The display device of claim 1, wherein:
the first glass substrate further comprises a fifth portion between the first portion and the second portion and having a first inclined surface; and
the second glass substrate further comprises a sixth portion between the third portion and the fourth portion and having a second inclined surface.

5. The display device of claim 1, wherein the resin layer comprises a first resin portion overlapping the folding region, a second resin portion overlapping the first non-folding region, and a third resin portion overlapping the second non-folding region.

6. The display device of claim 5, wherein the first resin portion comprises:
a first sub-resin portion adjacent to the display panel; and
a second sub-resin portion having a Young's modulus different from that of the first sub-resin portion, and positioned below the first sub-resin portion.

7. The display device of claim 6, wherein the Young's modulus of the first sub-resin portion is different from a Young's modulus of the second resin portion and a Young's modulus of the third resin portion.

8. The display device of claim 6, wherein the first sub-resin portion is between the second portion and the fourth portion, and the second sub-resin portion is between the first portion and the third portion.

9. The display device of claim 5, wherein:
the second resin portion overlaps the second portion, and does not overlap the first portion; and
the third resin portion overlaps the fourth portion, and does not overlap the third portion.

10. The display device of claim 5, wherein a thickness of the first resin portion is greater than a thickness of the second resin portion and a thickness of the third resin portion.

11. The display device of claim 1, wherein the resin layer comprises a thermosetting resin or a photo-curable resin.

12. The display device of claim 1, wherein at a temperature of 25° C., the Young's modulus of the resin layer is 100 MPa or less.

13. The display device of claim 1, wherein the support adhesive layer does not comprise a pressure sensitive adhesive (PSA).

14. The display device of claim 1, wherein the support adhesive layer comprises a first adhesive layer and a second adhesive layer spaced from each other in a second direction crossing the first direction.

15. The display device of claim 1, wherein the support adhesive layer comprises:
a first region overlapping the first glass substrate or the second glass substrate, and not overlapping the resin layer; and
a second region overlapping the resin layer.

16. The display device of claim 15, wherein a portion of the second region overlaps the folding region.

17. The display device of claim 1, wherein the support adhesive layer comprises a base portion and an adhesive portion above the base portion.

18. The display device of claim 1, wherein the support adhesive layer further comprises a sub-adhesive portion below the base portion.

19. The display device of claim 1, further comprising a metal layer below the support adhesive layer and not overlapping the folding region.

20. The display device of claim 1, further comprising a polymer film overlapping the folding region, the first non-folding region, and the second non-folding region, and directly below the support adhesive layer.
